(19) United States
(12) Patent Application Publication
(10) Pub. No.: US 2005/0287299 A1
(43) Pub. Date: Dec. 29, 2005

(54) Method and apparatus using large-area organic vapor deposition for formation of organic thin films or organic devices

(76) Inventors: Seong Deok Ahn, Daejeon-city (KR); Yong Eui Lee, Seoul (KR); Seung Youl Kang, Daejeon-city (KR); Kyung Soo Suh, Daejeon-city (KR); Mi Kyung Kim, Daejeon-city (KR); Meyoung Ju Joung, Daejeon-city (KR); Chul Am Kim, Kyungki-do (KR); Myoung Ki Lee, Anyang-city (KR); Young Kyoo Jee, Suwon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/211,111

(22) Filed: Aug. 23, 2005

Related U.S. Application Data
(62) Division of application No. 10/672,013, filed on Sep. 26, 2003.

(30) Foreign Application Priority Data
Sep. 28, 2002 (KR) 2002-59133

(51) Int. Cl. C23C 16/00

(52) U.S. Cl. 427/248.1

(57) ABSTRACT

Provided are an apparatus and method using large-area organic vapor phase deposition for formation of organic thin films and organic devices. The apparatus includes a deposition part and a source part. The deposition part includes a process chamber; a substrate holder installed in the process chamber for supporting a loaded substrate; a substrate temperature controller installed in the substrate holder for controlling the temperature of the substrate; and a shower head installed opposite the substrate holder in the process chamber for uniformly distributing onto the substrate organic source vapors to be used for a deposition reaction. The source part includes a source chamber for generating organic source vapors to be supplied to the shower head; a source heater which surrounds the source chamber and allows organic materials to evaporate to be organic source vapors in the source chamber; and a transfer gas supply source for supplying transfer gas that is used to transfer the organic source vapors to the process chamber.

This application claims priority to Korean Patent Application No. 2002-59133, filed on Sep. 28, 2002, in the Korean Intellectual Property Office, the contents of which are incorporated herein by reference in its entirety.

### BACKGROUND OF THE INVENTION

1. Field of the Invention

The present invention relates to deposition of organic thin films or organic devices. More particularly, the present invention relates to an apparatus and method using large-area organic vapor phase deposition (OVPD), which is suitable for low-pressure formation of uniform organic thin films or organic devices, such as organic semiconductor devices or organic light-emitting devices.

2. Description of the Related Art

Vacuum evaporation methods are typically applied in the formation of organic thin films or organic devices, such as organic semiconductor devices and organic light-emitting devices. In a vacuum evaporation method, a thermal evaporation source container is installed in a vacuum chamber where a deposition process is to be performed, and substrates are loaded into the chamber to form organic thin films on the substrates.

In order to form organic thin films by vacuum evaporation methods, initially, a vacuum is formed and maintained by a vacuum chamber using a vacuum pump coupled thereto. One or more thermal evaporation source containers, which are installed within the vacuum chamber, induce organic materials to evaporate in the vacuum chamber. Then, the vaporized organic materials are transferred to and deposited on a substrate as an organic thin film.

The thermal evaporation source, that is, organic material, is put in a cylinder or square-type container. The container is formed of a heat-resistant material, such as quartz or ceramic. A heater is coiled around the container, and when power is supplied to the heater, the container is heated. As the container is heated to a predetermined temperature, organic materials start to evaporate depending on their vapor pressures.

The temperature of the container is measured by a thermocouple installed in the container. The container can be maintained at a constant temperature by controlling the heater by the thermocouple, thus achieving a desired evaporation rate of organic materials. The vaporized organic materials are delivered onto the substrate, which is loaded apart from the container by a predetermined distance, and then deposited as thin films through a sequence of reactions such as absorption, deposition, and re-evaporation.

Because organic materials (or organic precursors) for organic thin films have a high vapor pressure and may thermally decompose at a temperature nearing their evaporation temperatures, it is difficult to stabilize the evaporation of such organic materials for a long duration of time. Accordingly, the deposition rate of organic materials cannot be effectively controlled using conventional vacuum evaporation methods.

Also, vaporized organic materials for thin films are transferred to a limited region of a substrate in a vacuum chamber, depending on the shape of an upper portion of the thermal evaporation source container. Thus, it is difficult to form uniform organic thin films on a large-area substrate. Further, to form uniform organic thin films on a large-area substrate using conventional vacuum evaporation methods or apparatuses, an equivalent large-sized thermal evaporation source container is required. However, in this case, significantly increased amount of organic materials than required must be used, thereby lowering productivity. In consideration of the foregoing defects, it is difficult to mass-produce high-quality devices at a low cost.

FIG. 1 is a schematic diagram of a deposition apparatus using a conventional vacuum evaporation method.

Referring to FIG. 1, a crucible 60 is installed as a container of organic materials within a vacuum chamber 10. An appropriate amount of deposition material is estimated and put in the crucible 60, and then the vacuum chamber 10 is maintained at a reduced pressure of about 10⁻⁶ Torr. Next, the temperature of the crucible 60 is controlled using a heater 50 to be increased up to about the melting point of the deposition material. Afterwards, the temperature of the crucible 60 is controlled again and increased until the deposition material starts to evaporate.

Once the deposition material in the crucible 60 starts to evaporate, a crucible shutter 70 and a substrate shutter 40 are opened to allow molecules of the vaporized material to reach the substrate 30 placed on a substrate heater 20. Thus, a deposition reaction occurs on the substrate 30. Here, the crucible shutter 70 and the substrate shutter 40 are used to prevent undesirable impurities remaining in the vacuum chamber 10 from depositing on the substrate 30 immediately before the deposition reaction. Meanwhile, a monitor 80 is installed within the chamber 10 to assess the thickness of deposited thin films.

In a conventional vacuum evaporation apparatus, although only a small amount of deposition material is required, since it is difficult to estimate the precise amount of deposition material required, a large amount of deposition material must be put in the crucible 60. Thus, depending on how expensive the deposition material is, the vacuum evaporation process can be very costly. Also, because it is difficult to orient vaporized materials in a desired direction on the substrate 30, several re-deposition processes may be necessary. As a result, the inside of the vacuum chamber 10 is under the treat of becoming seriously contaminated, thus requiring subsequent cleaning process every time it is used. Further, it is difficult to obtain thin films having desired thickness by fine-tuning variables that affect the thickness of deposited thin films, such as the amount of a deposition material, the opening/shutting times of the crucible shutter 70 and the substrate shutter 40, and the evaporation time caused by temperature control.

To solve the foregoing problems, variety of techniques and methods have been developed and proposed. For example, according to Stephen R. Forrest, like in horizontal-type low-pressure chemical vapor deposition, organic materials contained in a crucible are heated and transferred in the vapor phase along with transfer gas to deposit organic thin films on a substrate (U.S. Pat. No. 5,554,220, dated Sep. 10, 1996, entitled “Method and apparatus using organic vapor phase deposition for the growth of organic thin film with large optical non-linearities” and U.S. Pat. No. 6,337,102, dated Jan. 8, 2000, entitled “Low pressure vapor phase deposition of organic thin film”). Also, according to Dong-Soo Kim, it is possible to deposit organic thin films on a large area in a high vacuum environment by adjusting the shape of a crucible and an inlet hole of organic vapors (Korean Patent Publication No. 2002-0038625, dated May 23, 2002, entitled “Method and apparatus using vapor phase deposition of organic films”).

Nevertheless, many problems remain unsolved and laborious studies on the formation of large-area uniform organic thin films are being conducted.

### SUMMARY OF THE INVENTION

The present invention provides an apparatus and method using large-area OVPD, by which the thickness and the composition of organic thin films can be fine-tuned.

In accordance with an aspect of the present invention, there is provided an apparatus using large-area OVPD for formation of organic thin films and organic devices.

The apparatus using OVPD comprises a deposition part and a source part. The deposition part includes a process chamber; a substrate holder installed in the process chamber for supporting a loaded substrate; a substrate temperature controller installed in the substrate holder for controlling the temperature of the substrate; and a shower head installed opposite the substrate holder in the process chamber for uniformly distributing organic source vapors to be used for a deposition reaction onto the substrate. The source part includes a source chamber for generating organic source vapors to be supplied to the shower head; a source heater which surrounds the source chamber and allows organic materials to evaporate to be organic source vapors in the source chamber; and a transfer gas supply source for supplying transfer gas that is used to transfer organic source vapors to the process chamber.

Here, the apparatus may further comprise a shower curtain, which is installed between the shower head and the substrate holder.

The apparatus may further comprise a transfer gas transfer line and an organic source vapor transfer line. The transfer gas transfer line is extended from the transfer gas supply source into the source chamber and includes a transfer gas inlet, which is formed in a portion extended into the source chamber of the transfer gas transfer line and allows the transfer gas to enter the source chamber. Also, the organic source vapor transfer line is extended from the shower head into the source chamber and includes an organic source vapor outlet, which allows the organic source vapors transferred by the transfer gas to exit the source chamber.

The source chamber may further include a transfer gas distributor, which is installed in the source chamber to distribute source gas fed from the transfer gas inlet.

The transfer gas distributor may have a shape of a conic block or conic plate, of which apex is aligned with the transfer gas inlet.

The source heater is expandable to surround the organic source vapor transfer line.

The apparatus may further comprise a diluted gas supply source, from which diluted gas is supplied along with organic source vapors to the process chamber.

Also, the apparatus may further comprise a regulator for controlling the flow rate and speed of fluids fed into the process chamber.

The apparatus may comprise a plurality of source chambers for generating different types of organic source vapors.

Here, the apparatus may further comprise a plurality of transfer lines, which are installed to allow different organic vapors to sequentially enter the process chamber or bypass using time-division, as well as a plurality of valves, which are installed to use the transfer lines by time-division.

In the apparatus, the source heater is expandable to heat the transfer lines and the valves.

In accordance with another aspect of the present invention, there is provided a method of using OVPD for formation of organic thin films and organic devices.

The method using OVPD comprises generating first organic source vapors by heating a source chamber containing a first organic material; transferring the first organic source vapors via a transfer line, which is maintained at a constant temperature to prevent condensation of the first organic source vapors, to a shower head of a process chamber; causing a deposition reaction by distributing the first organic source vapors transferred via the shower head onto a substrate that is loaded at a position opposite the shower head; and purging the process chamber after the vapor deposition is completed.

Here, causing a deposition reaction and purging the process chamber may be sequentially repeated.

To form multi-component organic thin films, the method may further comprise forming second organic source vapors by heating an additional source chamber containing the first organic material and a second organic material; transferring the second organic source vapors via another transfer line, which is maintained at a constant temperature to prevent condensation of the second organic source vapors, to the shower head of the process chamber; causing a second deposition reaction by distributing the second organic source vapors transferred via the shower head onto the substrate that is loaded at a position opposite the shower head; and second-purging the process chamber after the second vapor deposition is completed.

Here, the first organic source vapors and the second organic source vapors may be alternately supplied to the process chamber using time-division by about 0.01 second to several hours.

According to the present invention, uniform organic thin films can be deposited on a large-area substrate at a high deposition rate. Also, when a plurality of organic thin films are deposited or when one organic material, metal, or inorganic material is doped into another organic thin film, it is possible to fine-tune the thickness and the composition of organic thin films and the doping amount.

### BRIEF DESCRIPTION OF THE DRAWINGS

The above and other features and advantages of the present invention will become more apparent by describing in detail preferred embodiments thereof with reference to the attached drawings in which:

FIG. 1 is a schematic view of a deposition apparatus using a conventional vacuum evaporation method;

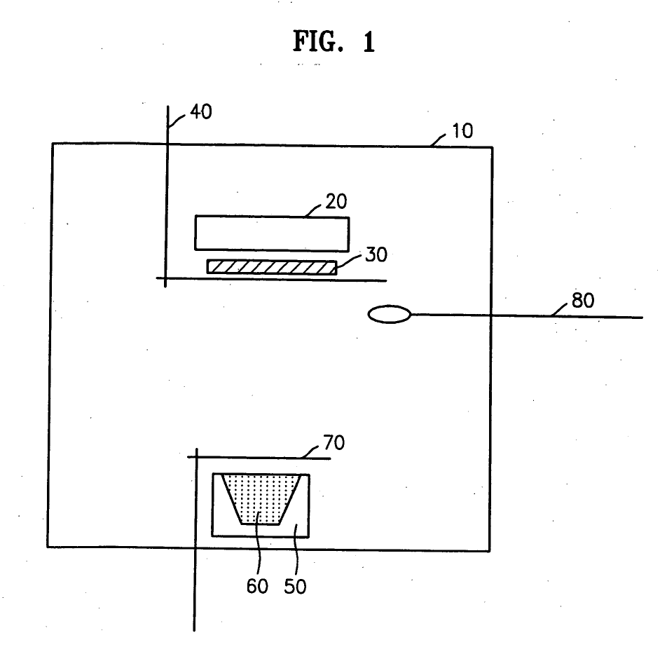

FIG. 2 is a schematic view of an apparatus using OVPD according to an embodiment of the present invention; and

FIG. 3 is a schematic view of a source chamber as shown in FIG. 2.

### DETAILED DESCRIPTION OF THE INVENTION

The present invention will now be described more fully with reference to the accompanying drawings, in which preferred embodiments of the invention are shown.

In an embodiment of the present invention, a new low-pressure apparatus of organic vapor phase deposition (OVPD) is proposed. The OVPD apparatus according to the embodiment of the present invention comprises a shower head and a source chamber. The shower head allows distribution of uniform organic vapors onto a substrate for forming organic thin films, and the source chamber contains each organic material to be delivered to the shower head in vapor phase. Also, when multi-component organic thin films are formed by alternately supplying organic vapors obtained from evaporation of respective organic materials to a process chamber, their thickness and composition can be fine-tuned by supplying time-division.

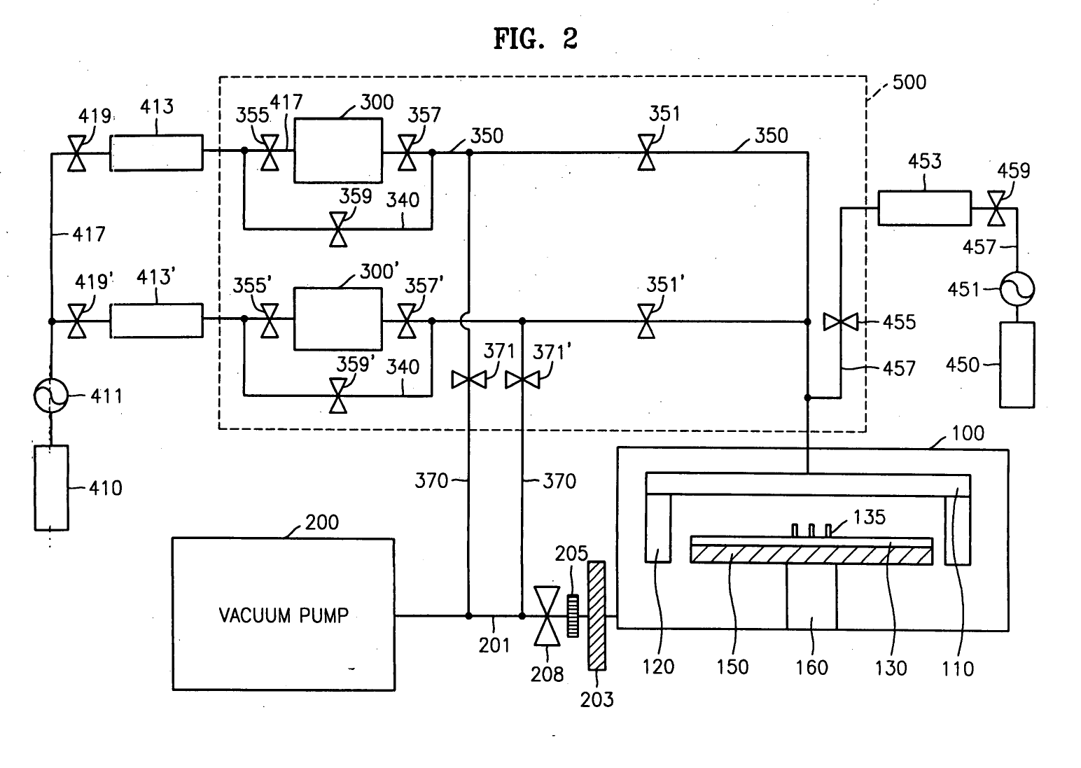

FIG. 2 is a schematic view of an apparatus using OVPD according to the embodiment of the present invention.

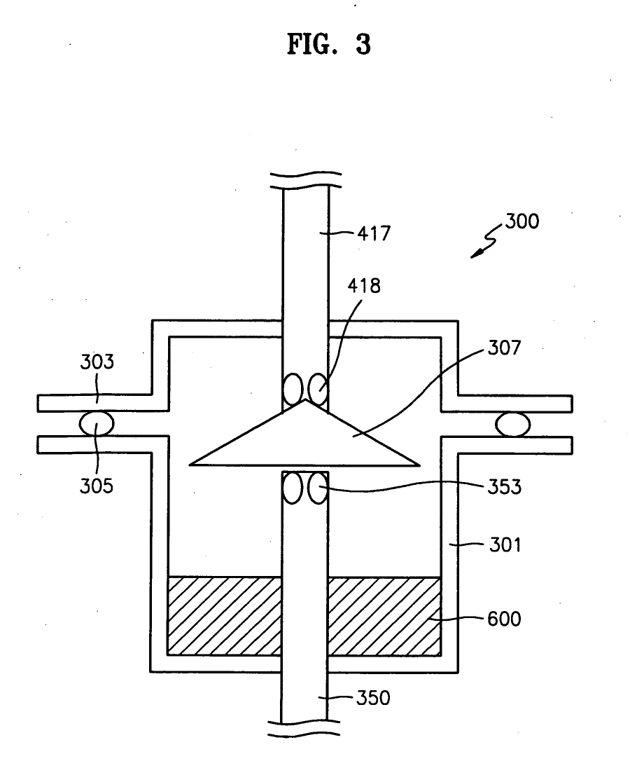

FIG. 3 is a schematic view of a source chamber as shown in FIG. 2.

Referring to FIG. 2, the OVPD apparatus according to an embodiment of the present invention includes a process chamber 100 where organic thin films are deposited. A vacuum pump 200 is coupled to the process chamber to maintain vacuum environment at a constant level. The vacuum pump 200 (e.g., a typical rotary pump) maintains the chamber 100 at a pressure of about 0.001 Torr to 100 Torr. Also, the vacuum pump 200 may further include a turbo pump to achieve a higher degree of vacuum.

A vacuum exhaust line 201, or a tube, is coupled between the vacuum pump 200 and the process chamber 100, and a trap 203 may be installed in the vacuum exhaust line 201. The trap 203 is formed as a cold trap in order to selectively remove gases of particular components. For example, in a case where a turbo pump is used as the vacuum pump 200, by-products such as water vapor, which may adversely affect the performance of the turbo pump, are selectively removed. That is, after an organic thin film is deposited, remaining by-products are condensed in the trap 203 to prevent degradation of the vacuum pump 200. Generally, the trap 203 is filled with liquid nitrogen, natural oil, or fluorocarbon oil.

A throttle valve 205 is installed at a rear end of the trap 203. The throttle valve 205 is placed on the vacuum exhaust line 201 near the connection between the process chamber 100 and the vacuum exhaust line 201. The throttle valve 205 regulates the pressure in the process chamber 100. Meanwhile, to perform a bypass operation, a quick switching valve 208 for a process chamber may be further installed to switch a bypass path to the process chamber 100, that is, to control the exhaust from the process chamber 100.

A source chamber 300 is installed to supply reaction gas (e.g., organic vapors) to the process chamber 100 where a vacuum environment will be formed by means of the vacuum pump 200. Source chambers 300 and 300′ are coupled to the process chamber 100 via a source vapor transfer line 350. Organic vapors, which are generated from organic materials in the source chamber 300, enter the process chamber 100 by transfer gas via the source gas vapor phrase transfer line 350.

When a plurality of organic materials are used to deposit thin films, a plurality of source chambers 300 and 300′ may be installed in parallel. Here, a plurality of source vapor transfer lines 350 are installed as a branch type to permit the plurality of source chambers 300 and 300′ to alternately feed different types of organic vapors into the process chamber 100. Also, a process chamber gas in quick switching valve 351 may be installed at a branch and reliably control each independent supply of various vapors.

Meanwhile, a transfer gas supply source 410 is coupled to the source chamber 300 via a transfer gas transfer line 417 to supply transfer gas to the source chamber 300. To fine-tune the uniform supply of the transfer gas to the source chamber, a regular valve 411 for supplying transfer gas is installed in the middle of the transfer gas transfer line 417, and a regulator 413 is installed at a rear end of the regular valve 411 to fine-tune the flow rate of transfer gas. In the case where the plurality of source chambers 300 and 300′ are installed, the transfer gas transfer line 417 is branched to be coupled to the respective source chambers 300 and 300′, and each quick switching valve 419 for distributing transfer gas is installed at a rear end of each branch to selectively supply transfer gas or independently control the supply of transfer gas.

The transfer gas may be an inert gas such as nitrogen, helium, argon, krypton, xenon, neon and the like. The transfer gas passes through the source chamber 300 to deliver vaporized organic vapors from the source chamber 300 or 300′ to the process chamber 100. The source chambers 300 and 300′ are where organic materials evaporate to generate organic vapors and lead the transfer gas to transfer the organic vapors to the process chamber 100.

Referring to FIG. 3, the source chamber 300 is formed of stainless steel or quartz. As shown in FIG. 2, a heating-block-type source heater 500 for heating the source chamber 300 is placed near the source chamber 300 to aid the evaporation of organic materials put in the source chamber 300.

The source heater 500 as shown in FIG. 2 not only heats the source chamber 300 but also expands to surround the source vapor transfer line 350 in order to prevent condensation of organic vapors delivered from the source chamber 300 to the source vapor transfer line 350. The expanded source heater 500 is used to control the temperatures of the source vapor transfer line 350 and its related valves. Also, the source heater 500 enables the independent temperature control of the source vapor transfer line 350 and the source chambers 300 and 300′. For example, the source heater 500 can apply a different amount of heat to each of the source vapor transfer line 350 and the source chambers 300 and 300′ such that the temperature of the source vapor transfer line 350 is lower than that of the source chamber 300 and 300′.

Referring again to FIG. 3, the source chamber 300 includes a lower body 301 containing an organic material 600 and an upper body 303 placed over the lower body 301. A gasket 305 is positioned between the lower body 301 and the upper body 303 to seal the source chamber 300. The organic material 600 contained in the source chamber 300 evaporates due to heat energy, which is applied from the source heater (500 of FIG. 2) heating the source chamber 300.

The transfer gas transfer line 417, which penetrates the upper body 303 of the source chamber 300, is expanded into the source chamber 300 and coupled to the source vapor transfer line 350 penetrating the lower body 301 of the source chamber 300. A transfer gas inlet 418 and a source vapor outlet 353 are formed at the connection between the transfer gas transfer line 417 and the source vapor transfer line 350. That is, the transfer gas inlet 418 is formed at a rear end of the transfer gas transfer line 417 to feed transfer gas into the source chamber 300, and the source vapor outlet 353 is formed at a front end of the source vapor transfer line 350 to exhaust source vapors via the source vapor transfer line 350. Here, the transfer gas inlet 418 and the source vapor outlet 353 are each formed of a plurality of holes. The holes may have a circular shape or any other shapes. The dimension of the holes may range from about 1 mm to 10 mm.

A transfer gas distributor 307 is installed between the rear end of the transfer gas inlet 418 and the front end of the source vapor outlet 353. The transfer gas distributor 307 is used to distribute the transfer gas fed into the source chamber 300. The transfer gas enters the source chamber 300 via the transfer gas transfer line 417 and the transfer gas inlet 418 and is distributed along inclined planes of the transfer gas distributor 307, which preferably includes conic plates or conic blocks. The distributed transfer gas, which includes uniform organic vapors of the organic material 600, is exhausted via the source vapor outlet 353 and delivered via the source vapor transfer line 350 to the process chamber 100 along with the organic vapors.

While the transfer gas distribution gas 307 for distributing transfer gas has a conic shape, it may have any other shape that enables distribution of the transfer gas and be varied in its height or length.

To deposit organic thin films in the process chamber 100, a bypass operation is performed before organic vapors are delivered to the process chamber 100 by feeding transfer gas into the source chamber as described above with reference to FIG. 3. The organic vapors are bypassed by opening a source out quick switching valve 355, a source in quick switching valve 357, and a source bypass quick switching valve 371. To perform the bypass operation, a bypass path 370 is installed as a tube to directly couple the source vapor transfer line 350 and the vacuum exhaust line 201. The source bypass quick switching valve 371 is installed in the middle of the bypass path 370 to open/shut off the bypass path 370.

After the bypass operation is completed, the source bypass quick switching valve 371 is shut off and the gas in quick switching valve 351 is opened to allow organic vapors mixed with the transfer gas to enter the process chamber 100 via the source vapor transfer line 350. All of the gas transfer lines and the source chamber 300, which follow the regulator 413, may be heated by means of the heating-block-type source heater 500. Here, each of the transfer lines and the source chamber 300 may include a plurality of sub-heaters, each of which enables the independent temperature control. The source heater 500 heats the transfer lines and related valves from a room temperature up to a high temperature of about 500° C.

Meanwhile, referring again to FIG. 2, organic vapors are fed into the process chamber 100 along with diluted gas. For this, a diluted gas supply source 450 for supplying diluted gas is coupled to the process chamber 100 via a diluted gas transfer line 457. To fine-tune the uniform supply of the diluted gas to the process chamber 100, a regular valve 451 for supplying diluted gas is installed in the middle of the diluted gas transfer line 457 and a regulator 453 for diluted gas is installed at a rear end of the regular valve 451 to fine-tune the flow rate of the diluted gas. A quick switching valve 459 is installed at a front end of the regulator 453, and a source chamber gas in quick switching valve 455 for a diluted gas line is installed at a rear end of the regulator 453 to control the supply of the diluted gas by its opening/shutting off.

The diluted gas, which is used to control the entire pressure of the process chamber 100, enters the process chamber 100 via the source vapor transfer line 350 and enables low-pressure deposition of organic thin films. The diluted gas may be an inert gas such as nitrogen, helium, argon, krypton, xenon, neon and the like. Alternately, the diluted gas may be a reactive gas, such as ammonia and methanol, or hydrogen that hardly reacts on organic materials.

Accordingly, when organic vapors are fed into the process chamber 100 to form organic thin films, the source chamber gas in quick switching valve 455 for the diluted gas line is opened/shut off to control the entire pressure of the process chamber 100.

The source vapor transfer line 350, which is extended into the process chamber 100, is coupled to the shower head 110 installed at an inner upper portion of the process chamber 100 and supplies reactive gas (e.g., organic source vapors) to the shower head 110. The shower head 110 distributes the organic source vapors onto a substrate (not shown) loaded on a substrate holder 130, which is installed at an inner lower portion of the process chamber 100 to face the shower head 110, and allows organic thin films to be deposited on the substrate. The substrate holder 130 may include lift pins 135, which support a wafer or a substrate loaded into the process chamber 100 to affix it on the substrate holder 130. To affix the wafer or the substrate on the substrate holder 130, the lift pins 135 perform rising/falling operations by means of a pin cylinder (not shown), which may be installed in a support axis 160 supporting the substrate holder 130. Also, the lift pins 135 are used to adjust the distance between the shower head 110 and a substrate. The support axis 160 may be coupled to a motor positioned outside the process chamber 100 to rotate the substrate support 130 or supply driving power for rising/falling operations.

Although not shown in detail, the shower head 110 includes a plurality of plates, each having inner space into which reaction gas will be supplied. Also, the lowest plate of the plates, which faces the substrate holder 130, includes a plurality of jet orifices (not shown) to allow uniform distribution of the reaction gas per area. Here, the number of the plates ranges from 1 to 5, and the reaction gas (e.g., the organic gas source vapors) is uniformly distributed to the plurality of jet orifices included in the lowest plate by filing the spaces between the plates and penetration paths formed by the plates. The jet orifices can be formed to a dimension of about 0.01 mm to 50 mm. Preferably, although not shown in the drawings, the shower head 110 includes a shower head heater, which can maintain the shower heat at a constant temperature to prevent condensation of the organic vapor passing through the shower head.

Since the shower head 110 uniformly distributes and supplies reaction gas (e.g., organic vapors) to a substrate loaded on the substrate holder 130, uniform organic thin films can be formed by the reactions of the organic vapors. The shower head 110 can have a circular or square shape to uniformly supply organic vapors, diluted gas, or the like to the substrate.

Meanwhile, a substrate temperature controller 150 may be installed below the substrate holder 130 to control the temperature of the substrate holder 130. Although not shown in detail, the temperature controller 150 includes cooling lines and a substrate heater, which is used to heat or cool a substrate to permit deposition of uniform organic thin films.

Also, a shower curtain 120 may be installed between the substrate holder 130 and the shower head 110 to surround the substrate holder 130. The shower curtain 120 can be attached/detached to allow the diameter rate of the shower head 110 and the substrate holder 130 to be varied.

Meanwhile, after organic thin films are formed in the process chamber 100, tubes (e.g., the organic source vapor transfer line 350) between the respective source chambers 300 and the process chamber 100 are cleaned. To clean the tubes, the source out quick switching valve 355, the source in quick switching valve 357, and the source bypass quick switching valve 370 are shut off and the source purge quick switching valve 359 and the process chamber gas in quick switching valve 351 are opened. Thus, a predetermined amount of inert gas is fed into the process chamber 100 to enable all of the by-products remaining in gas lines and the process chamber 100 to exit the process chamber 100. To perform the cleaning process, a purge gas transfer line 340, which bypasses the source chamber 300, is installed to directly couple the transfer gas transfer line 417 and the source vapor transfer line 350.

Meanwhile, in a case where a single organic thin film is pre-processed and a multi-component organic thin film is deposited, the number of source chambers 300 may be increased. Also, organic thin films can be deposited using time-division in order to control the accurate thickness and pre-processed amount of thin films and the doping extent.

An example of depositing a multi-component organic thin film by time-division using the apparatus of the present invention will be described as follows.

Referring to FIG. 2, firstly, a first deposition process is performed. That is, a first source chamber 300 is driven by opening a first source out quick switching valve 355, a first source in quick switching valve 357, and a first process chamber gas in quick switching valve 351. Thus, a first organic thin film is deposited on a substrate loaded in a process chamber 100.

Secondly, a first purge process is performed. The process chamber 100 is purged by opening a first source purge quick switching valve 359 and a first process chamber gas in quick switching valve 351 to allow remaining organic materials to exit the process chamber 100. During the purge process, organic materials are directly transferred to a vacuum pump 200 by opening a second source out quick switching valve 355′, a second source in quick switching valve 357′, and a second source bypass quick switching valve 371′ to maintain the steady-state flow. Here, a second process chamber gas in quick switching valve 351′ may be shut off.

Thirdly, a second deposition process is performed. A second organic thin film is deposited by opening the second source out quick switching valve 355′, the second source in quick switching valve 357′, and the second process chamber gas in quick switching valve 351′. Here, the first source out quick switching valve 355, the first source in quick switching valve 357, and the first process chamber gas in quick switching valve 351 may be shut off.

Fourthly, a second purge process is performed. Remaining organic materials exit the process chamber 100 by opening a second source purge quick switching valve 359′ and the second process chamber gas in quick switching valve 351′. During the purge process, organic materials are directly transferred to the vacuum pump 200 by opening the first source out quick switching valve 355, the first source in quick switching valve 357, and the first bypass quick switching valve 371 to maintain the steady-state flow.

By repeating the first through fourth steps, it is possible, for example, to deposit AB, ABAB, ABABAB, and . . . −type organic thin films, where each letter denotes a different molecular layer or composition. The method of depositing organic vapors using time-division is very effective to fine-tune the thickness and the doping amount of organic thin films.

The remaining organic materials can be exhausted from the process chamber by way of the vacuum pump 200. Meanwhile, as described above, valves used for time-division are preferably capable of operating at a temperature of normal temperature to 500° C. This is because transfer lines are heated to prevent condensation of organic source vapors. Also, these valves preferably perform on/off operations with time precision of 0.05 seconds or less.

The apparatus of the present invention can introduce a variety of substrates, which are formed of metals, semiconductors, insulators, or plastics. Also, these substrates can have, various shapes such as circle, square, rectangle or the like. In particular, a plastic substrate can be modified into a “roll-to-roll” substrate. In the present invention, as a shower head is used to uniformly distribute reaction gas (e.g., organic source vapors) onto a large-area substrate, a wide variety of substrates can be used.

As described above, according to the present invention, uniform organic thin films can be deposited on a large-area substrate at high speed. When a plurality of organic thin films are deposited or when an organic material is doped into a thin film formed of another organic material, the thickness and the composition of organic thin films can be fine-tuned using time-division. The time-division method can be realized using a plurality of source chambers and transfer lines, which couple the source chambers and process chambers.

While the present invention has been particularly shown and described with reference to preferred embodiments thereof, it will be understood by those of ordinary skill in the art that various changes in form and details may be made therein without departing from the spirit and scope of the present invention as defined by the following claims.

1. A method using organic vapor phase deposition comprising:
generating first organic source vapors by heating a source chamber containing a first organic source material;
transferring the first organic source vapors via a transfer line, which is maintained at a constant temperature to prevent condensation of the first organic source vapors, to a shower head of a process chamber;
causing a deposition reaction by distributing the first organic source vapors transferred via the shower head onto a substrate that is loaded at a position opposite the shower head; and
purging the process chamber after the vapor deposition is completed.

2. The method of claim 1, further comprising sequentially repeating causing a deposition reaction and purging the process chamber.

3. The method of claim 1, to form multi-component organic thin films, further comprising:
forming second organic source vapors by heating an additional source chamber containing the first organic material and a second organic material;
transferring the second organic source vapors via another transfer line, which is maintained at a constant temperature to prevent condensation of the second organic source vapors, to the shower head of the process chamber;
causing a second deposition reaction by distributing the second organic source vapors transferred via the shower head onto the substrate that is loaded at a position opposite the shower head; and
second-purging the process chamber after the second vapor deposition is conducted on the substrate.

4. The method of claim 3, wherein the first organic source vapors and the second organic source vapors are alternately supplied to the process chamber using time-division by about 0.01 second to several hours.
